(19) United States
(12) Patent Application Publication
(10) Pub. No.: US 2009/0291539 A1
(43) Pub. Date: Nov. 26, 2009

(54) METHOD FOR MANUFACTURING AND LCD DRIVER IC

(76) Inventor: Duck-Ki Jang, Bucheon-si (KR)

Correspondence Address: SHERR & VAUGHN, PLLC, 620 HERNDON PARKWAY, SUITE 320, HERNDON, VA, 20170, US

(21) Appl. No.: 12/265,843

(22) Filed: Nov. 6, 2008

(30) Foreign Application Priority Data
Nov. 6, 2007 (KR) 10-2007-0112578

(51) Int. Cl. H01L 21/8238; H01L 21/336; H01L 21/762

(52) U.S. Cl. 438/224; 438/303; 438/231; 257/E21.409; 257/E21.546; 257/E21.634; 257/E21.642

(57) ABSTRACT

A method of manufacturing an LCD driver chip includes forming a heavily doped P-type well and a heavily doped N-type well over a high voltage region of a substrate; and then forming an oxide layer over the heavily doped P-type well and the heavily doped N-type; and then simultaneously forming a first gate electrode over the heavily doped P-type well and a second gate electrode over the heavily doped N-type well including the oxide layer; and then patterning the oxide layer to form a gate insulating layer under the first and second gate electrodes and an oxide layer portion connected to lateral sides of the gate insulating layers; and then forming an insulating layer over the entire surface of the substrate including the first and second gate electrodes and the oxide layer portion; and then forming spacers on sidewalls of the first and second gate electrodes and then removing the oxide layer portion after forming the spacers; and then forming ion implantations regions over the heavily doped P-type well and the heavily doped N-type well.

The present application claims priority under 35 U.S.C. §119 to Korean Patent Application No. 10-2007-0112578 (filed Nov. 6, 2007), which is hereby incorporated by reference in its entirety.

### BACKGROUND

An LCD Driver IC (LDI) controls each section of a screen that is divided into a plurality of sections, and several drivers IC are used for each panel. An LDI is provided with a high voltage transistor including a high voltage device and a low voltage device. In an LDI, current leakage frequently occurs in a high voltage device of the LDI. Although the current leakage is within 30 pA per unit width, such a current leakage may cause a latch up, so that the LDI may not operate properly. Although a drain contact area and a source contact area must be formed in an ohmic contact, since N+ or P+ ion implantation for a low voltage device serving as a logic device is performed in common with the high voltage device, the high voltage device is merged with the low voltage device, so that the high voltage device fails to have a sufficient implant depth of N+ or P+ dopants

### SUMMARY

Embodiments relate to a method of manufacturing an LCD driver IC (LDI) that prevents current leakage from occurring in a high voltage device due to an absence of an ohmic contact.

Embodiments relate to a method of manufacturing an LCD driver chip that may include at least one of the following: forming a low voltage device on and/or over a substrate; forming a drift region for a high voltage device by forming a shallow trench isolation layer at a side of the low voltage device; forming an oxide layer on and/or over an entire area of the drift region; forming a gate electrode on and/or over the oxide layer; etching the oxide layer while leaving a portion of the oxide layer at both sides of the gate electrode; forming an insulating layer on and/or over an entire surface of the substrate including the remaining oxide layer; forming a spacer by selectively etching the insulating layer while exposing the remaining oxide layer; removing the exposed remaining oxide layer; and performing a contact ion implantation relative to the low voltage device and the high voltage device.

Embodiments relate to a method that may include at least one of the following: forming a low voltage device over a substrate; and then forming a first shallow trench isolation layer laterally to the low voltage device; and then forming a heavily doped P-type well and a heavily doped N-type well over the substrate; and then forming N-type drift regions spaced apart over the heavily doped P-type well; and then forming P-type drift regions spaced apart over the heavily doped N-type well; and then forming an oxide layer over the heavily doped P-type well, the P-type drift regions, the heavily doped N-type well and the N-type drift regions; and then simultaneously forming a gate electrode over the heavily doped P-type well and the heavily doped N-type well including the oxide layer; and then patterning the oxide layer to form a first oxide layer portion under the gate electrode and a second oxide layer portion connected to lateral sides of the first oxide layer pattern; and then forming an insulating layer over the entire surface of the substrate including low voltage device; and then simultaneously forming spacers on sidewall as of the low voltage device and the gate electrode and exposing the second oxide layer portion; and then removing the second oxide layer portion; and then forming ion implantations regions over the low voltage device and the heavily doped P-type well and the heavily doped N-type well; and then forming a contact plug over the ion implantations regions.

Embodiments relate to a method that may include at least one of the following: forming a heavily doped P-type well and a heavily doped N-type well over a high voltage region of a substrate; and then forming an oxide layer over the heavily doped P-type well and the heavily doped N-type; and then simultaneously forming a first gate electrode over the heavily doped P-type well and a second gate electrode over the heavily doped N-type well including the oxide layer; and then patterning the oxide layer to form a gate insulating layer under the first and second gate electrodes and an oxide layer portion connected to lateral sides of the gate insulating layers; and then forming an insulating layer over the entire surface of the substrate including the first and second gate electrodes and the oxide layer portion; and then forming spacers on sidewalls of the first and second gate electrodes and then removing the oxide layer portion after forming the spacers; and then forming ion implantations regions over the heavily doped P-type well and the heavily doped N-type well.

### DRAWINGS

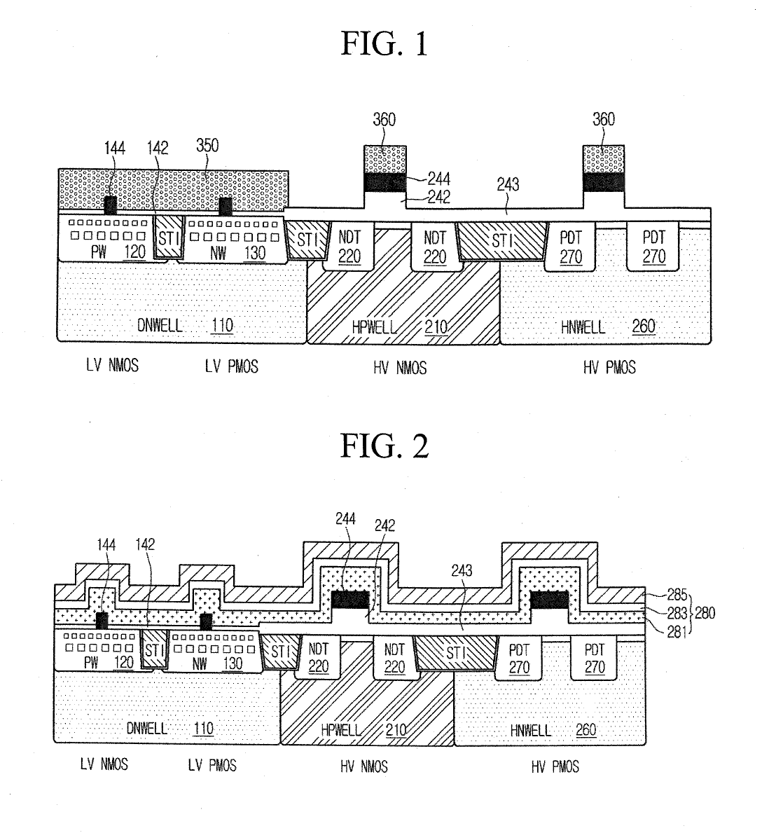

Example FIGS. 1 to 3B illustrate a method of manufacturing an LCD driver IC in accordance with embodiments.

### DESCRIPTION

Hereinafter, a method of manufacturing an LCD driver IC will be described with reference to accompanying drawings.

Example FIGS. 1 to 3B are sectional views representing a method of manufacturing an LCD driver IC in accordance with embodiments.

As illustrated in example FIG. 1, a low voltage (LV) device is formed on and/or over a substrate. For example, a deep N-type well 110 is formed in the substrate, and then a P-type well 120 and an N-type well 130 are formed by forming a shallow trench isolation (STI) layer in the deep N-type well 110. The deep N-type well 110 can be formed by implanting deep well ions and then performing an annealing process for a time duration in a range between approximately 500 to 1000 minutes at a temperature in a range between approximately 1000 to 1500° C. to diffuse the ions. Since a logic area can be isolated from a high voltage device area by the deep N-type well 110 in addition to the STI layer, even when a substrate bias is changed, impact exerted on a logic part is substantially reduced. Accordingly, an operating range of the high voltage device extends in a range from a VDD (+Voltage) to a substrate voltage (−Voltage), so that the adaptability of the device is maximized. After that, a low voltage gate insulating layer 142 and a gate electrode 144 are formed. The low voltage gate insulating layer 142 has a thickness in a range between approximately 20 to 30 Å.

Hereinafter, a process of forming a high voltage (HV) device will be described, in which the high voltage device is formed by forming a shallow trench isolation (STI) layer at a side of the low voltage device. A heavily doped P-type well (HPWELL) 210 and a heavily doped N-type well (HNWELL) 260 are formed on and/or over the substrate lateral to the deep N-type well (DNWELL) 110. The heavily doped P-type well (HPWELL) 210 is interposed between the deep N-type well (DNWELL) 110 and the heavily doped N-type well (HNWELL) 260. N-type drift regions (NDT) 220 are formed spaced apart on and/or over the heavily doped P-type well 210. P-type drift regions (PDT) 270 are formed spaced apart on and/or over the heavily doped N-type well 260. After that, an oxide layer is formed on and/or over the entire area of the drift regions 220, 270. For example, the oxide layer has a thickness in a range between approximately 700 to 900 Å.

Sequentially, a gate electrode 244 is formed on and/or over the oxide layer by forming a polysilicon layer on and/or over the entire area of the oxide layer and then etching the polysilicon layer using a first photoresist pattern 360 as an etching mask. A second photoresist pattern 350 is formed on the entire area of the low voltage device area to prevent the low voltage device from being etched. After that, a portion of the oxide layer is etched using the first photoresist pattern 360 as an etching mask to simultaneously form an oxide layer 243 and a gate oxide layer 242. The oxide layer is etched through a dry etching, for example, a plasma dry etching. The oxide layer 243 is formed in order to minimize damage caused by plasma. For example, the oxide layer 243 has a thickness in a range between approximately 170 to 220 Å.

As illustrated in example FIG. 2, the first and second photoresist patterns 360 and 350 are then removed, and an insulating layer 280 is formed on and/or over the entire surface of the substrate including the oxide layer 243 and the gate electrode 244. For example, the insulating layer 280 may have an ONO structure including a first oxide layer 281, a nitride layer 283 and a second oxide layer 285. The first oxide layer 281 has a thickness in a range between approximately 180 to 220 Å, the nitride layer 283 has a thickness in a range between approximately 180 to 220 Å and the second oxide layer 285 has a thickness in a range between approximately 700 to 900 Å.

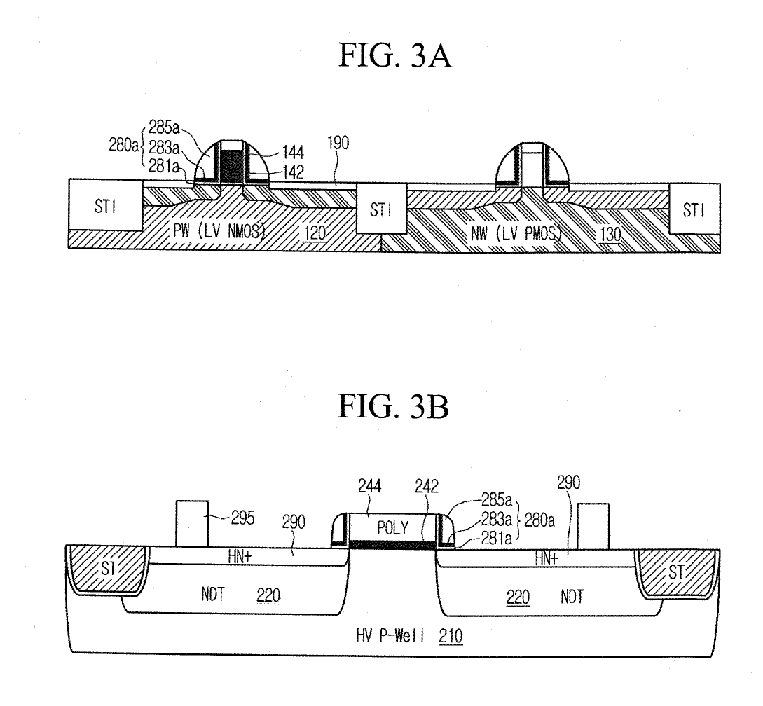

As illustrated in example FIGS. 3A and 3B, the insulating layer 280 is then selectively etched to form a spacer 280a while exposing the oxide layer 243. Example FIG. 3A is a sectional view representing the low voltage device, and example FIG. 3B is a sectional view representing the high voltage device.

As illustrated in example FIG. 3A, the spacer 280a is formed at both sidewalls of the gate electrode 144 of the low voltage device. The spacer 280a includes an etched first oxide layer 281a, an etched nitride layer 283a and an etched second oxide layer 285a. In addition, as illustrated in example FIG. 3B, a spacer 280a is formed at both sidewalls of the gate electrode 244 of the high voltage device, so that the oxide layer 243 is exposed. After forming the spacer 280a at both sidewalls of the gate electrode 244 of the high voltage device, the exposed oxide layer 243 is removed. For example, the exposed remaining oxide layer 243 is removed through a wet etching. For example, the exposed remaining oxide layer 243 is removed by an HF solution. Since the HF is dilute acid including HF and H₂O mixed in a ratio in a range between approximately 1:90 to 1:110, the HF solution does not cause damage to the surface of the substrate. Since the exposed remaining oxide layer 243 is removed, a margin for a contact ion implantation can be ensured and a damage, which may occur when an etching process is performed while leaving a portion of the oxide, can be prevented. Then, contact ion implantations 190, 290 are performed on the low voltage device and the high voltage device, respectively. After that, a contact plug 295 is formed.

In the method of manufacturing the LCD driver IC according to the embodiment, the remaining oxide layer of the high voltage (HV) device is removed through the wet etching process, so that the ohmic contact is ensured by the N+ and P+ ion implantation.

Although embodiments have been described herein, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method comprising:
forming a drift region in a high voltage region of a substrate; and then
forming an oxide layer over the drift region; and then
forming a gate electrode over the oxide layer; and then
forming a gate oxide layer under the gate electrode by etching the oxide layer while leaving a portion of the oxide layer at both sides of the gate electrode; and then
forming an insulating layer over an entire surface of the substrate including the oxide layer and the gate electrode; and then
forming a spacer on sidewalls of the gate electrode by selectively etching the insulating layer while exposing the portion of the oxide layer at both sides of the gate electrode; and then
removing the exposed portion of the oxide layer; and then
performing a contact ion implantation process on the high voltage device.

2. The method of claim 1, wherein the exposed portion of the oxide layer is removed through a wet etching process.

3. The method of claim 2, wherein the exposed portion of the oxide has a thickness in a range between approximately 170 to 220 Å.

3. The method of claim 1, wherein the exposed portion of the oxide layer is removed using an HF solution.

4. The method of claim 3, wherein the HF solution is diluted using H₂O at a ratio in a range between approximately 1:90 to 1:110.

5. The method of claim 4, wherein the exposed portion of the oxide has a thickness in a range between approximately 170 to 220 Å.

6. A method comprising:
forming a low voltage device over a substrate; and then
forming a first shallow trench isolation layer laterally to the low voltage device; and then
forming a heavily doped P-type well and a heavily doped N-type well over the substrate; and then
forming N-type drift regions spaced apart over the heavily doped P-type well; and then
forming P-type drift regions spaced apart over the heavily doped N-type well; and then
forming an oxide layer over the heavily doped P-type well, the P-type drift regions, the heavily doped N-type well and the N-type drift regions; and then
simultaneously forming a gate electrode over the heavily doped P-type well and the heavily doped N-type well including the oxide layer;
patterning the oxide layer to form a first oxide layer portion under the gate electrode and a second oxide layer portion connected to lateral sides of the first oxide layer pattern;
forming an insulating layer over the entire surface of the substrate including the low voltage device; and then
simultaneously forming spacers on sidewalls of the low voltage device and the gate electrode and exposing the second oxide layer portion; and then
removing the second oxide layer portion; and then
forming ion implantations regions over the low voltage device and the heavily doped P-type well and the heavily doped N-type well; and then
forming a contact plug over the ion implantations regions.

7. The method of claim 6, wherein forming the low voltage device comprises:
forming a deep N-type well in the substrate; and then
forming a P-type well and an N-type well over the deep N-type well; and then
forming a second shallow trench isolation layer between the P-type well and the N-type well;
forming a gate insulating layer over the P-type well and the N-type well; and then
forming a gate electrode over the P-type well and the N-type well.

8. The method of claim 7, wherein the gate insulating layer has a thickness in a range between approximately 20 to 30 Å.

9. The method of claim 6, wherein the oxide layer has a thickness in a range between approximately 700 to 900 Å.

10. The method of claim 6, wherein forming the gate electrode comprises:
forming a polysilicon layer over the heavily doped P-type well and the heavily doped N-type well including the oxide layer; and then
forming a first photoresist pattern over the polysilicon layer and a second photoresist pattern over the low voltage device; and then
performing a first etching process on the polysilicon layer using the first photoresist pattern as an etching mask.

11. The method of claim 10, wherein simultaneously forming the first and second oxide layer patterns comprises:
performing a second etching process on the oxide layer using the first photoresist pattern as an etching mask; and then
removing the first photoresist pattern and the second photoresist pattern.

12. The method of claim 11, wherein the second etching process comprises a dry etching process.

13. The method of claim 12, wherein the dry etching process comprises a plasma etching.

14. The method of claim 6, wherein the oxide layer has a thickness in a range between approximately 170 to 220 Å.

15. The method of claim 6, wherein the insulating layer comprises an ONO structure including a second oxide layer, a nitride layer and a third oxide layer.

16. The method of claim 15, wherein the second oxide layer has a thickness in a range between approximately 180 to 220 Å, the nitride layer has a thickness in a range between approximately 180 to 220 Å and the third oxide layer has a thickness in a range between approximately 700 to 900 Å.

17. The method of claim 6, wherein the second oxide layer portion is removed through a wet etching process.

18. The method of claim 6, wherein the second oxide layer portion is removed using an HF solution.

19. The method of claim 18, wherein the HF solution is diluted using H₂O at a ratio in a range between approximately 1:90 to 1:110.

20. A method comprising:
forming a heavily doped P-type well and a heavily doped N-type well over a high voltage region of a substrate; and then
forming an oxide layer over the heavily doped P-type well and the heavily doped N-type; and then
simultaneously forming a first gate electrode over the heavily doped P-type well and a second gate electrode over the heavily doped N-type well including the oxide layer; and then
patterning the oxide layer to form a gate insulating layer under the first and second gate electrodes and an oxide layer portion connected to lateral sides of the gate insulating layers; and then
forming an insulating layer over the entire surface of the substrate including the first and second gate electrodes and the oxide layer portion; and then
forming spacers on sidewalls of the first and second gate electrodes and then removing the oxide layer portion after forming the spacers; and then
forming ion implantations regions over the heavily doped P-type well and the heavily doped N-type well.
